(19) United States
(12) Patent Application Publication
(10) Pub. No.: US 2008/0241991 A1
(43) Pub. Date: Oct. 2, 2008

(54) GANG FLIPPING FOR FLIP-CHIP PACKAGING

(75) Inventors: Anindya Poddar, Sunnyvale, CA (US); Jaime A. Bayan, Palo Alto, CA (US); Ashok S. Prabhu, San Jose, CA (US); Will K. Wong, Daly City, CA (US)

Correspondence Address: Beyer Law Group LLP, P.O. BOX 1687, Cupertino, CA, 95015-1687, US

(73) Assignee: National Semiconductor Corporation

(21) Appl. No.: 11/691,428

(22) Filed: Mar. 26, 2007

(51) Int. Cl. H01L 21/00

(52) U.S. Cl. 438/106

(57) ABSTRACT

An improved method and apparatus for packaging integrated circuits are described. More particularly, a method and apparatus for use in securing a plurality of integrated circuit dice to a lead frame panel are described. Each integrated circuit die includes an active surface having a multiplicity of solder bumps. The lead frame panel includes an array of device areas, each including a plurality of leads. The method includes positioning a plurality of dice into designated positions on a carrier such that the active surfaces of the dice are facing upwards. The carrier includes a carrier frame including an associated array of carrier device areas. A lead frame panel may be positioned over the carrier such that the solder bumps on the active surfaces of the dice are adjacent and in contact with the associated leads of the associated device areas.

### BRIEF DESCRIPTION OF THE INVENTION

The present invention relates generally to the packaging of integrated circuits (ICs). More particularly, a method and apparatus for use in attaching dice to a substrate are described.

### BACKGROUND OF THE INVENTION

There are a number of conventional processes for attaching integrated circuit (IC) dice to printed circuit boards (PCB) or other desired substrates. Often the dice are packaged into a plastic or ceramic package. Such packages often utilize metallic lead frames. Each lead frame generally includes a plurality of leads that are electrically connected to associated I/O pads on the die. The lead frame also generally includes associated metallic contacts for electrically connecting the package to contacts on the PCB. Alternatively, the die itself may be directly connected to contacts on the PCB.

One type of die that may be packaged or directly connected to a PCB is known as a flip-chip style die. A flip-chip die generally has solder bumps formed on contact pads on the active surface of the die. After singulation from a wafer, the die may or may not be flipped over prior to packaging or attachment to a suitable substrate. During attachment, the solder bumps are directly connected to contact pads on the substrate. Suitable substrates include lead frames, ball grid arrays (BGAs) and PCBs, among others.

While existing flip-chip packaging methods and systems work well, there are continuing efforts to develop even more efficient methods and systems.

### SUMMARY OF THE INVENTION

A method of securing a plurality of integrated circuit dice to a lead frame panel is described. Each integrated circuit die includes an active surface and a back surface. The active surface of the die includes a multiplicity of contact pads having solder bumps formed thereon. The method includes positioning a plurality of dice into designated positions on a carrier such that the active surfaces of the dice are facing upwards away from the carrier. A lead frame panel that includes a plurality of device areas is placed over the dice populated carrier. With this arrangement, solder bumps on the active surfaces of the dice are positioned adjacent and in contact with the associated leads of the associated device areas. After the lead frame panel has been positioned, the solder bumps are reflowed to attach the dice to the lead frame panel. With this arrangement the contact pads on the dice are mechanically and electrically coupled to the leads of associated device areas of the lead frame panel. After reflow, the lead frame panel and attached dice may be separated from the carrier. In a preferred embodiment, the carrier may then be reused in attaching other dice.

In another embodiment, a carrier suitable for use in attaching integrated circuit dice to a lead frame panel is described. The lead frame panel includes an array of device areas, each device area including a plurality of leads. The carrier includes a carrier frame including an associated array of associated carrier device areas. Each carrier device area is suitably sized to receive an associated integrated circuit die. More particularly, when a die is suitably positioned within each carrier device area and when the lead frame panel is appropriately positioned adjacent the carrier, the leads of the lead frame device areas are adjacent and in contact with associated solder bumps on top of the contact pads on the associated dice.

### BRIEF DESCRIPTION OF THE DRAWINGS

For a better understanding of the invention, reference should be made to the following detailed description taken in conjunction with the accompanying drawings, in which:

FIG. 1 is a flow chart illustrating a process for attaching solder bumped dice in accordance with an embodiment of the present invention;

FIGS. 2A-2C illustrate diagrammatic top views of a lead frame panel suitable for use in attaching flip-chip dice in accordance with an embodiment of the present invention;

FIGS. 3A-3C illustrate diagrammatic top views of a carrier suitable for use in attaching flip-chip dice in accordance with an embodiment of the present invention;

FIGS. 4A-4D illustrate diagrammatic side views of various stages in the process of FIG. 1 in accordance with an embodiment of the present invention;

FIGS. 5A-5B illustrate diagrammatic top and side views of a carrier suitable for use in attaching flip-chip dice in accordance with another embodiment of the present invention; and

FIG. 6A-6D illustrate diagrammatic side views of various stages in the process of FIG. 1 in accordance with an another embodiment of the present invention.

Like reference numerals refer to corresponding parts throughout the drawings.

### DETAILED DESCRIPTION OF THE DRAWINGS

The invention relates generally to the packaging of integrated circuits (ICs). More particularly, a method and apparatus for use in attaching a plurality of dice to a substrate are described.

In the following description, numerous specific details are set forth to provide a thorough understanding of the present invention. It will be apparent, however, to one skilled in the art that the present invention may be practiced without some or all of these specific details. In other instances, well known process steps have not been described in detail in order to avoid unnecessary obscuring of the present invention.

The following description focuses on the packaging of flip-chip style dice utilizing lead frames in a flip chip on lead (FCOL) package style. However, it is contemplated that the present invention may be advantageously practiced in the packaging of a variety of dice into a variety of package configurations in which solder bumps on the dice are to be directly electrically connected with metallic contacts on a substrate.

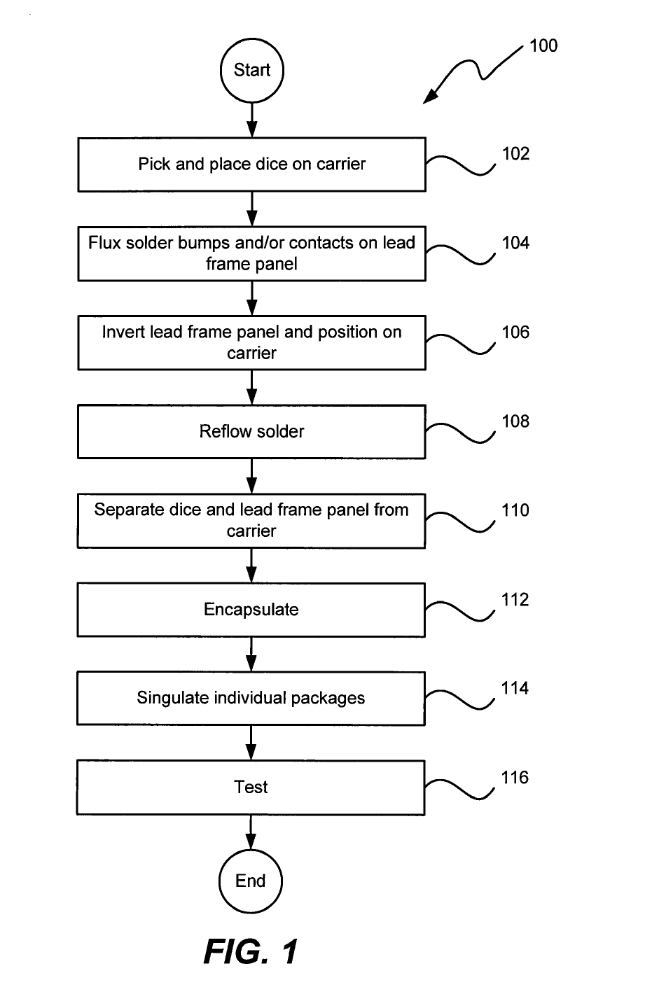

Various embodiments of the present invention will now be described with reference to FIGS. 1-6. Aspects of the present invention provide a method and apparatus for packaging flip-chip dice using a conventional die attach machine. More particularly, a method and apparatus are described for picking up and positioning flip-chip dice onto a suitable substrate using a die attach machine that is not configured for use as a flip-chip die attach machine.

Flip-chip die attach machines, in general, are considerably more expensive than conventional (non-flip-chip) die attach machines. By way of example, flip-chip die attach machines may presently cost upwards of approximately $500,000 compared with roughly $150,000-$200,000 for conventional die attach machines. Furthermore, conventional die attach machines are generally significantly faster than flip-chip machines. By way of example, a conventional die attach machine may presently attach upwards of 10,000-15,000 dice per hour. Conversely, flip-chip die attach machines may be capable of attaching fewer than 4,000 dice per hour. Flip-chip die attach machines do offer advantages, however, such as the ability to process high pin count devices. However, these high pin count capabilities are not required for many applications. More particularly, many applications, such as those employing dice suitable for use in micro surface-mount devices (SMDs), require very low pin counts. It is thus desirable to adapt the packaging process such that high speed conventional die attach machines may be used to attach flip-chip dice to substrates.

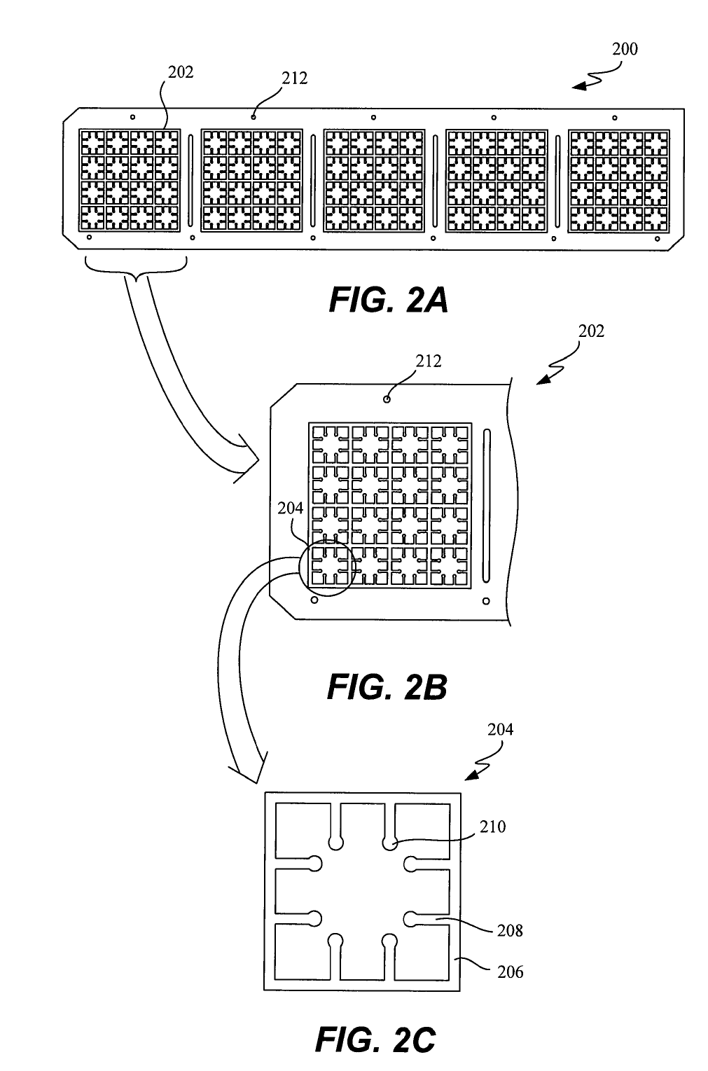

Referring initially to FIG. 1, and further in view of FIGS. 2-4, a process 100 of attaching flip-chip integrated circuit dice to a substrate in accordance with one embodiment of the present invention will be described. The described method facilitates the simultaneous mass positioning of a plurality of dice onto associated device areas of a substrate for subsequent attachment. In particular, a plurality of dice are first positioned onto a temporary carrier. The substrate is then positioned onto the carrier and dice such that each die is adjacent to an associated device area of the substrate.

In a preferred embodiment, the substrate is a lead frame panel. In the illustrated embodiment, the lead frame panel is in the form of a lead frame strip. FIG. 2A illustrates a diagrammatic top view of a lead frame panel 200 arranged in the form of a strip. The lead frame panel 200 is configured as a metallic structure with a number of two-dimensional arrays 202 of device areas. As illustrated in the successively more detailed FIGS. 2B-C, each two-dimensional array 202 includes a plurality of device areas 204, each configured for use in a single IC package, and each connected by fine tie bars 206. Each device area 204 includes a plurality of leads 208, each supported at one end by the tie bars 206. Each lead 208 includes a contact region 210 at the distal end of the lead.

In other embodiments, the substrate may be a substrate suitable for use in ball grid array (BGA) or land grid array (LGA) packages, among others.

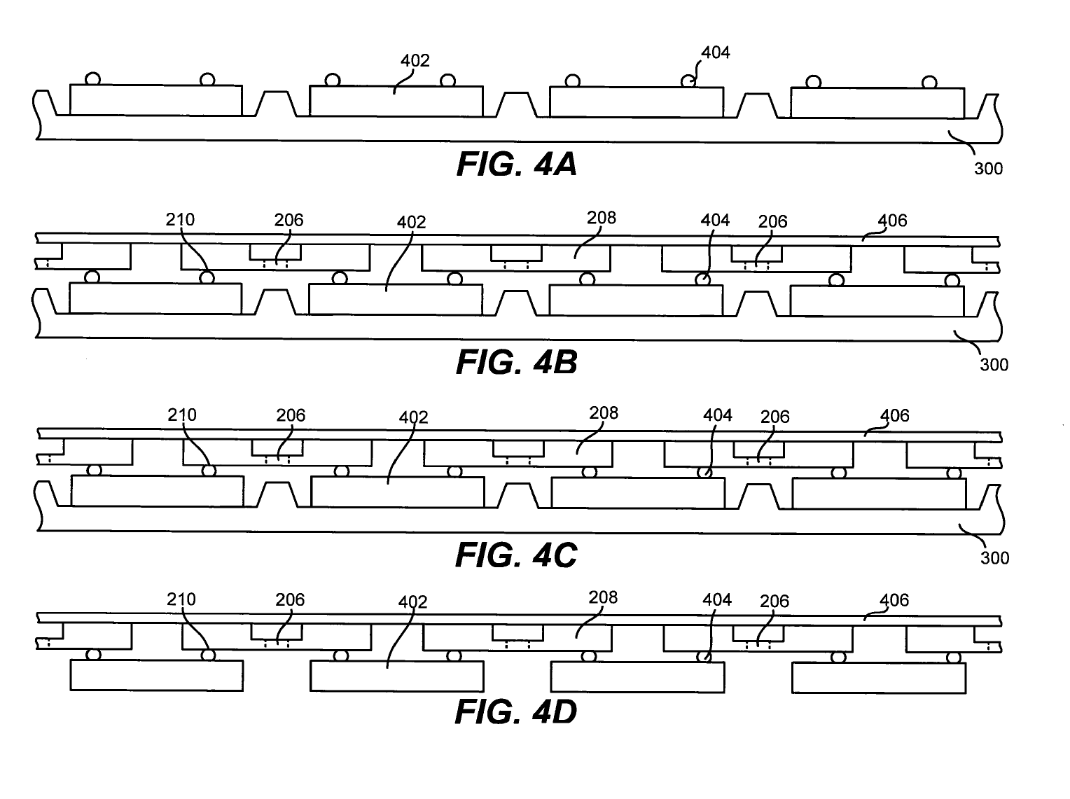

Process 100 begins at 102 with the positioning of individual solder bumped dice 402 onto a carrier 300. FIG. 4A illustrates a side view of a cross-section of the carrier 300 populated with dice 402. In a preferred embodiment, each die 402 is positioned onto the carrier 300 using a conventional die attach machine. More particularly, the die attach machine does not flip each die 402 over prior to placement onto the carrier 300, as is generally done by flip-chip die attach machines. In the illustrated embodiment, the dice 402 are placed onto the carrier 300 such that active surfaces of the dice are facing upwards away from the carrier. In the illustrated embodiment, each of the dice also includes a plurality of solder balls, contacts or solder bumps 404 on the active surfaces of the dice that are intended to be mounted directly onto contact regions 210 of the lead frame panel 200. The solder bumps 404 may be formed directly on I/O pads on the die or redistributed to alternate contact pads using conventional redistribution techniques. Additionally, underbump metallization stacks (UBMs) may be formed on the contact pads of the die 402 prior to solder bumping to produce the solder bumps 404.

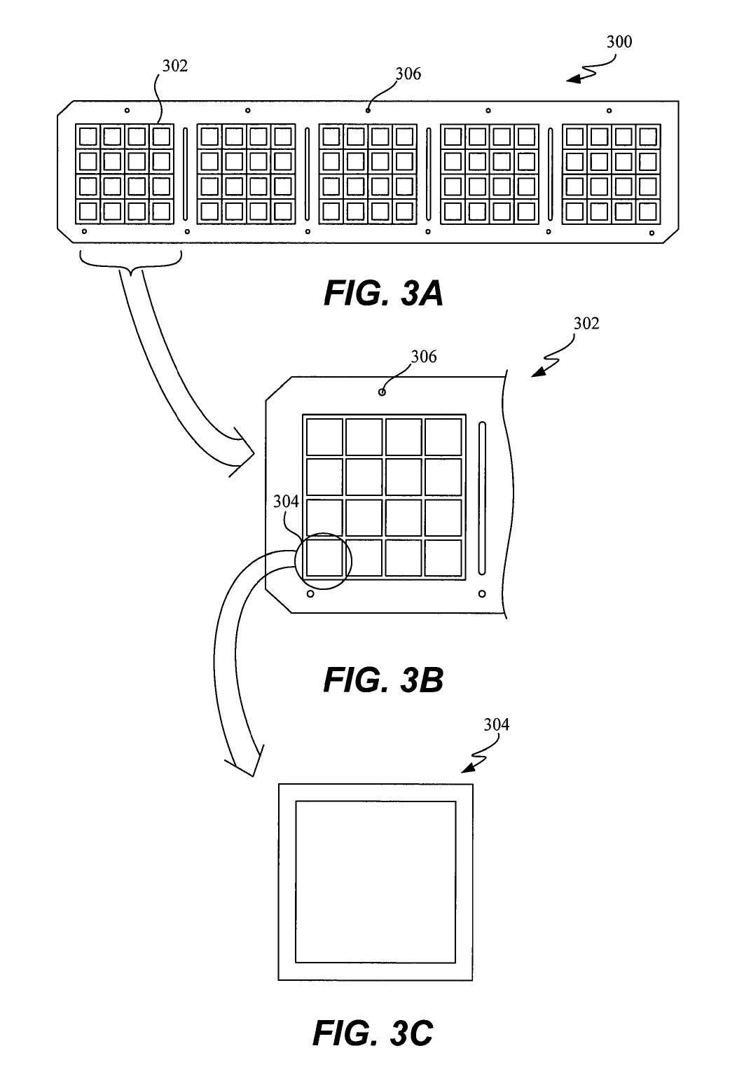

The carrier 300 may assume a wide variety of structural forms and configurations. Preferably, the carrier 300 is constructed from a metallic frame. By way of example, the carrier 300 may be made of copper or a copper alloy similar to that used in constructing metallic lead frames. FIG. 3A illustrates one embodiment of the carrier 300 arranged in the form of a strip. FIGS. 3B-3C illustrate successively more detailed views of the carrier 300 illustrated in FIG. 3A.

In the illustrated embodiment, the carrier 300 includes a number of two-dimensional arrays 302. Each array 302 includes a plurality of die holding cavities 304. Each die holding cavity 304 is configured to receive a single die 402. By way of example, each holding cavity may be a recessed region in the carrier. Alternatively, each cavity 304 may be a through-hole extending entirely through the carrier. Preferably, the two-dimensional arrays 302 correspond to associated two-dimensional arrays 202 of an associated lead frame panel 200. Additionally, each die holding cavity 304 preferably corresponds to an associated device area 204 on the associated lead frame panel 200. More particularly, the carrier 300 is configured such that when an associated lead frame panel 200 is inverted and positioned on top of the populated carrier, the device areas 204 on the lead frame panel are positioned directly adjacent to the dice 402 on the carrier.

In some embodiments, each die 402 is “held” in its associated cavity 304 by a thin film of liquid placed onto the bottom surface 306 of the cavity. The surface tension of the thin film of liquid helps hold the die 402 in place within the cavity 304. The thin film may be formed of any suitable liquid. Preferred liquids will have low viscosity and will evaporate during reflow without leaving any residue. By way of example, water-soluble fluxes work well. In an alternate embodiment, each cavity 304 may include an inlet on the bottom surface of the cavity. Each inlet may be coupled via a vacuum line to a vacuum source. In this way, the dice 402 may be secured within the cavities 304 by means of vacuum.

In some embodiments, an adhesive tape is secured to the back surface of the carrier 300. The tape is particularly useful in embodiments in which each cavity 304 includes a through-hole large enough to receive an associated die. In this way, the tape supports the dice 402 in the carrier. Additionally, the back surfaces of the dice 402 may be adhered to the tape in order to hold the dice in place while the lead frame panel is placed over the carrier 300.

Generally, at 104, flux is applied to the solder bumps 404 and/or the contact regions 210 on the substrate. In some embodiments, the carrier 300 and attached dice 402 are flipped over and dipped in a reservoir of flux to apply flux to the solder bumps 404 on the dice. In another embodiment, the contact regions 210 on the lead frame panel 200 are prepared with flux. Fluxing the contact regions 210 may be accomplished using a stamp transfer method similar to that used by many conventional die attach machines to apply epoxy during conventional die attachment. In this embodiment, an apparatus including a single pin or plurality of pins may be used to deliver flux to each contact region 210 on the lead frame panel 200. More particularly, ends of the pin or pins may be dipped in a reservoir of flux. Subsequently, the pin or pins may then be stamped onto contact regions 210 on the lead frame panel 200 thereby transferring the flux to the contact region(s). In a preferred embodiment, a “bed” of pins may be used to deliver flux to each lead frame contact region 210 simultaneously. In this “gang-fluxing” approach, the bed of pins is dipped into a reservoir of flux. The bed of pins is arranged such that when stamped onto the lead frame panel 200, each pin applies flux to an associated contact region 210 simultaneously.

Subsequently, at 106 the lead frame panel 200 is placed over the carrier 300, as illustrated in FIG. 4B. In some embodiments, this may require inverting the lead frame panel 200. In the illustrated embodiment, the lead frame panel 200 includes an adhesive tape 406 attached to the back bottom surface of the lead frame panel opposite the carrier 300. By way of example, the adhesive tape 406 is generally a high temperature tape, such as a polyimide tape, suitable for use during encapsulation of the lead frame panel. The lead frame panel 200 is positioned directly over the dice 402. More particularly, the lead frame panel 200 is set directly onto the solder bumps 404 on the active surfaces of the dice 402 that are supported by the carrier 300. Although not explicitly shown in the particular cross section illustrated in FIG. 4B, it should be appreciated that the leads in the device areas 204 of the lead frame panel 200 are supported by the tie bars 206.

As is well known in the art, lead frame panel strips 200 often include alignment holes 212 located in the support rails positioned on the sides of the panel. The alignment holes 212 are generally used to align the lead frame panel 200 with a mold having associated alignment pins during encapsulation of the lead frame panel and dice 402. In a preferred embodiment, the carrier 300 additionally includes alignment pins 306 that correspond to associated alignment holes 212 in the lead frame panel 200. In this manner, the lead frame panel 200 can be precisely positioned relative to the carrier 300.

After the lead frame panel 200 is situated on the carrier 300, the carrier, dice 402 and lead frame panel are generally placed in a reflow oven for reflow of the solder bumps 404 at step 108. In the illustrated embodiment, spacers are placed onto the pins 306 prior to setting the lead frame panel 200 onto the carrier 300. By way of example, the spacers may be cylindrical spacers placed over and around the pins 306. The spacers may be advantageously used to control the collapse of the solder bumps 404 during reflow when the solder bumps are melted. More particularly, during reflow of the solder bumps 404, the solder bumps will melt and collapse under the weight of the lead frame panel 200. However, when spacers are used in between the carrier 300 and the lead frame panel 200, the lead frame panel will collapse onto the spacers. Thus, the thickness of the spacers may be chosen to achieve a precisely controlled standoff height between the dice 402 and the lead frame panel 200. Furthermore, it should be appreciated that the spacers facilitate a uniform resultant standoff height across each individual device area 204 as well as across the entire lead frame panel 200.

During the reflow process, the thin film of liquid is evaporated in embodiments in which a liquid is used to hold the dice 402 in position within the cavities 304. In embodiments in which a vacuum is used to secure the dice 402, the vacuum may be decoupled from the carrier 300 prior to reflow. After situating the lead frame panel 200 onto the dice 402, the weight of the lead frame panel itself may be sufficient to hold the dice in position.

After reflow, the dice 402 are mechanically and electrically connected to the lead frame panel 200 via the solder bumps 404, as illustrated in FIG. 4C. It should be appreciated that spacers positioned over the pins 306 may be used to control the collapse of the solder bumps 404 during reflow, thus permitting control over the resultant standoff height. The lead frame panel 200 and attached dice 402 are separated from the carrier 300 at 110 as is illustrated in FIG. 4D. In a preferred embodiment, the carrier 300 may then be reused in the attachment of another lot of dice to another lead frame panel. In embodiments in which an adhesive tape is adhered to the back surface of the carrier 300, the tape is removed and replaced. Following separation from the carrier, the populated lead frame panel 200 may be placed in a mold for encapsulation with a molding material at 112. Preferably, the entire populated lead frame panel 200 is encapsulated substantially simultaneously. Subsequently, the encapsulated lead frame panel may then be singulated at 114 to provide a plurality of individual IC packages. Generally, the individual IC packages are then tested at 116.

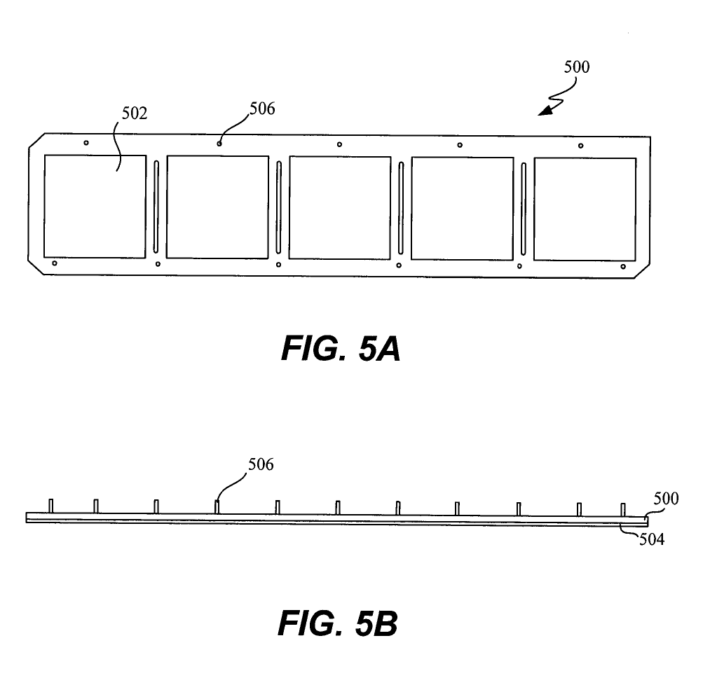

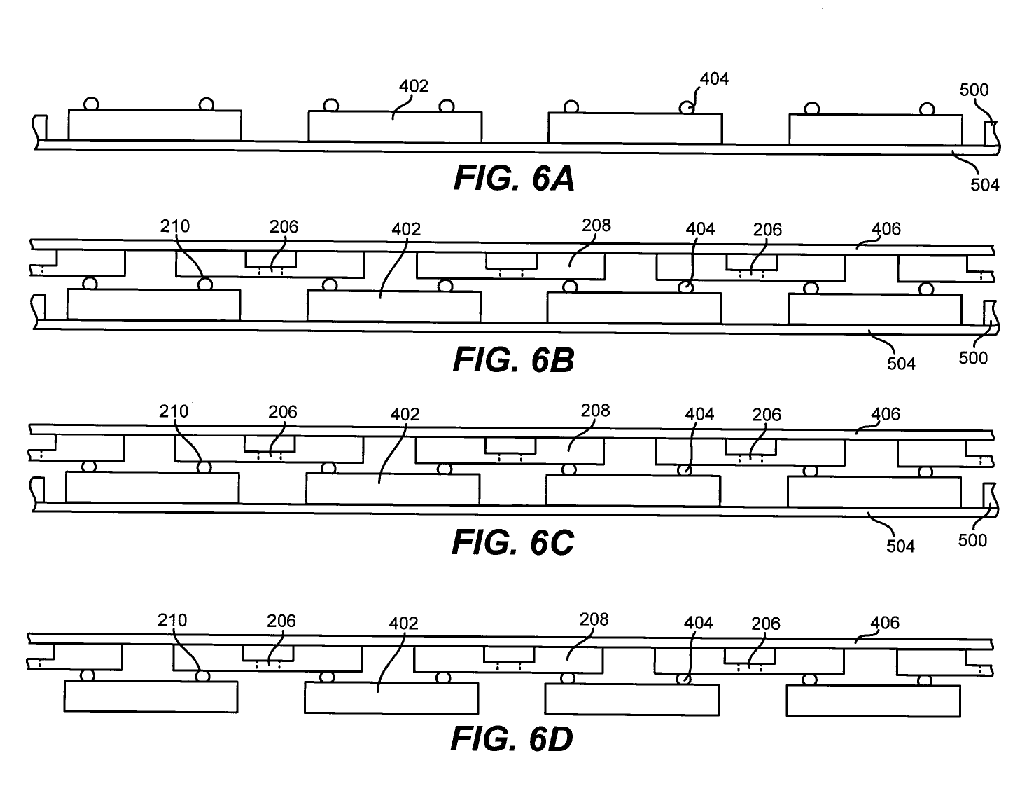

In an alternate embodiment, with reference to FIGS. 5-6, a carrier 500 is described that is also constructed from a metallic frame. FIG. 5A illustrates a top view of the carrier 500 while FIG. 5B illustrates a side view of the carrier. However, rather than including a plurality of cavities 304, the carrier 500 includes a number of large cutout regions 502. In a preferred embodiment, the carrier 500 includes a cutout region 502 for each two-dimensional array 202 of device areas of an associated lead frame panel 200. Each cutout region 502 is preferably similar in geometry and may be slightly larger than the associated two-dimensional array 202. A layer of tape 504 is adhered to the back surface of the carrier 500 to cover at least each cutout region 502. In this embodiment, rather than placing dice 402 into associated cavities 304, the dice are placed directly onto the tape 504 as illustrated in FIG. 6A. In this manner, back surfaces of the dice 402 become adhered to the tape 504, eliminating the need for a vacuum or liquid to secure the dice to the carrier 500. Subsequently, as before, the lead frame panel 200 is positioned over the dice 402 and carrier 500 as illustrated in FIG. 6B. Again, the carrier 500 may also include pins 506 that correspond with associated alignment holes 212 in the lead frame panel 200. The carrier 500, dice 402 and lead frame panel 200 may then be placed in a reflow oven. It should be noted that the tape 504 is preferably a high-temperature tape capable of withstanding the high temperatures experienced during reflow. By way of example, a high-temperature polyimide tape may be used.

In one embodiment the dice 402 remain adhered to the tape 504 during reflow. After reflow, the dice 402 are mechanically and electrically connected to the lead frame panel 200 via the solder bumps 404 as illustrated in FIG. 6C. Again, it should be appreciated that spacers positioned over the pins 506 may be used to control the collapse of the solder bumps 404 during reflow, thus permitting control over the resultant standoff height. The lead frame panel 200 and attached dice 402 may be separated from the carrier 500 and tape 504 as illustrated in FIG. 6D. Upon separation, a new layer of tape 504 may be adhered to the back surface of the carrier 500. Subsequently, the carrier 500 may be used in attaching a new lot of dice 402 to a new lead frame panel 200. It should be appreciated that the carrier 500 may be used in attaching dice 402 to a variety of lead frame configurations due to the open nature of the carrier 500 and the use of the tape 504.

It should be appreciated that the described methods and carriers 200 and 500 may be used in attaching solder bumped dice to a variety of substrates using a conventional die attach machine. Moreover, it should be appreciated that the described method allows for virtually complete integration with conventional die attach machines.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description. They are not intended to be exhaustive or to limit the invention to the precise forms disclosed. It will be apparent to one of ordinary skill in the art that many modifications and variations are possible in view of the above teachings.

The embodiments were chosen and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents.

What is claimed is:

1. A method of securing a plurality of integrated circuit dice to a lead frame panel, each integrated circuit die including an active surface and a back surface, the active surface having a multiplicity of contact pads having solder bumps formed thereon, the method comprising:
a) positioning a plurality of dice into designated positions on a carrier, wherein the active surfaces of the dice are facing away from the carrier;
b) placing a lead frame panel adjacent the carrier, the lead frame panel including a plurality of device areas, each device area including a plurality of leads and each device area corresponding to an associated die positioned on the carrier, wherein the solder bumps on the active surfaces of the dice are adjacent and in contact with associated leads of associated device areas; and
c) reflowing the solder to secure the dice to the lead frame panel.

2. A method as recited in claim 1, further comprising d) separating the lead frame panel and attached dice from the carrier after the solder has solidified.

3. A method as recited in claim 2, further comprising encapsulating portions of the lead frame panel and attached dice and singulating portions of the encapsulated lead frame panel to produce a plurality of individual integrated circuit packages.

4. A method as recited in claim 1, wherein the device area regions of the lead frame panel are not in physical contact with the carrier prior to reflow.

5. A method as recited in claim 2, further comprising:
reusing the carrier while repeating steps (a)-(d) using new dice and lead frame panels to populate additional lead frame panels with integrated circuit devices.

6. A method as recited in claim 1 wherein each designated position on the carrier includes a recessed cavity suitably sized to receive an associated die, a bottom surface of each cavity having a thin film of liquid deposited thereon, the method further comprising using surface tension from the thin films of liquid to hold the dice in place in their associated cavities.

7. A method as recited in claim 1 wherein each designated position on the carrier includes a vacuum source that communicates with each designated position, the method further comprising using the vacuum source to hold the dice in place in their associated positions.

8. A method as recited in claim 1 wherein each designated position on the carrier includes an adhesive tape adhered to the carrier, the method further comprising adhering back surfaces of the dice to the adhesive tape.

9. A carrier suitable for use in attaching integrated circuit dice to a lead frame panel, the lead frame panel including an array of device areas, each device area including a plurality of leads, the carrier comprising:
a carrier frame including an associated array of associated carrier device areas, each carrier device area being suitably sized to receive an associated integrated circuit die,
wherein when a die is suitably positioned within each carrier device area and when the lead frame panel is appropriately positioned adjacent the carrier, the leads of the lead frame device areas are adjacent and in contact with associated solder bumps on top of contact pads on associated dice.

10. A carrier as recited in claim 9, wherein the footprint of the carrier frame is substantially the same as the footprint of the associated lead frame panel and wherein the carrier frame is substantially formed from a metal or metallic alloy.

11. A carrier as recited in claim 9, further comprising a plurality of alignment pins that are positioned peripherally around the carrier frame and that correspond with alignment holes in the associated lead frame panel, wherein when the lead frame panel is positioned over the carrier, the pins of the carrier pass through the holes of the lead frame panel thereby aligning the lead frame panel to the carrier.

12. A carrier as recited in claim 11, further comprising a plurality of spacers positioned over and around the carrier pins.

13. A carrier as recited in claim 9, wherein each carrier device area includes a recessed cavity suitably sized to receive an associated die.

14. A carrier as recited in claim 13, further comprising a vacuum source that communicates with each cavity to facilitate holding the dice in place in their associated cavities.

15. A carrier as recited in claim 13, further comprising a thin film of liquid deposited on a bottom surface of the cavity, wherein each die is held in position within each cavity by surface tension from the thin film of liquid.

16. A carrier as recited in claim 13, wherein each carrier device area includes a through-hole suitably sized to receive an associated die, the carrier further including an adhesive tape adhered to a back surface of the carrier frame that serves as a support surface for the dice.

17. A carrier suitable for use in attaching integrated circuit dice to a lead frame panel, the lead frame panel including an array of device areas, each device area in the lead frame panel including a plurality of leads, the carrier comprising:
a carrier frame having a through hole, the through hole being suitably sized to receive a plurality of dice;
an adhesive tape adhered to a back surface of the carrier frame that serves as a support surface for a plurality of dice,
wherein a plurality of dice may be positioned within the through hole in an array such that back surfaces of the dice are adhered to the tape to populate the carrier with dice; and
wherein when the lead frame panel is appropriately positioned adjacent the populated carrier, the leads of the lead frame device areas are adjacent and in contact with associated solder bumps on their associated dice.

18. A carrier as recited in claim 17, wherein the footprint of the carrier frame is substantially the same as the footprint of the associated lead frame panel and wherein the carrier frame is substantially formed from a metal or metallic alloy.

19. A carrier as recited in claim 17, further comprising a plurality of alignment pins that are positioned peripherally around the carrier frame and that correspond with alignment holes in the associated lead frame panel, wherein when the lead frame panel is positioned over the carrier, the pins of the carrier pass through the holes of the lead frame panel thereby aligning the lead frame panel to the carrier.

20. A carrier as recited in claim 19, further comprising a plurality of spacers positioned over and around the carrier pins.
